(19) United States
(12) Patent Application Publication
(10) Pub. No.: US 2012/0074272 A1
(43) Pub. Date: Mar. 29, 2012

(54) ELECTRONIC DEVICE HOLDER

(76) Inventor: Joel Hull, Austin, TX (US)

(21) Appl. No.: 12/892,514

(22) Filed: Sep. 28, 2010

(51) Int. Cl. H05K 7/00; F16M 11/06; F16M 11/14

(52) U.S. Cl. 248/122.1; 248/121

(57) ABSTRACT

In some embodiments, provided is an electronic device holder including a body and one or more securing members coupled to the body. The securing members, during use, couple the body to an electronic device such that relative movement between the electronic device and the body is inhibited. The electronic device holder further includes a support member coupled to the body, the support member including an external shape grippable by a human hand such that a user can securely hold the electronic device by clutching the support member during use. During use, the support member bears at least a portion of the weight of the electronic device. The support member is coupled to the body such that the support member is angularly movable in three planes relative to the body during use.

### BACKGROUND

1. Field of the Invention

The present invention relates to the field of electronic device holders. In particular, embodiments relate to electronic device holders including a support member bearing at least a portion of the weight of the electronic device during use.

2. Description of the Related Art

In recent years, hand-held electronic devices such as tablet PCs, ebook readers, and personal digital assistants (PDAs) have been widely used in the healthcare, education, hospitality, and industrial fieldwork industries. For example, an electronic device may supplant handwritten or printed medical charts in a hospital, textbooks in a class room, and/or detailed technical drawings at an industrial plant. Such electronic devices are often held in one hand by a user during use while the other hand of the user operates the device. In some cases, it may be difficult for a user to securely hold the electronic device with just one hand. For example, the electronic device may be may be too wide to fit in the palm of the user's hand. U.S. Patent Publication No. 2004/0226973 to Kao (the entirety of which is incorporated herein by reference) describes a one-hand-holding aid for tablet personal computers.

Additionally, such electronic devices may be cumbersome to operate such while sitting down. For example, a user may either continue to hold the device in one hand or set the device flat on a table or desk, which limits the viewing range and angle. U.S. Patent Publication No. 2005/0121595 to Kuo (the entirety of which is incorporated herein by reference) describes a support stand for lifting a tablet personal computer at a predetermined angle.

### SUMMARY

Various embodiments of electronic device holders, as well as related apparatus and methods of using the same, are described. In some embodiments, an electronic device holder includes a body and one or more securing members coupled to the body. The securing members, during use, couple the body to an electronic device such that relative movement between the electronic device and the body is inhibited. The electronic device holder further includes a support member coupled to the body. The support member includes an external shape grippable by a human hand such that a user can securely hold the electronic device by clutching the support member during use. During use, the support member bears at least a portion of the weight of the electronic device. The support member is coupled to the body such that the support member is angularly movable in three planes relative to the body during use.

In some embodiments, an electronic device holder includes a body and a first securing member coupled to the body. The first securing member includes two or more elongated members extending outward from the body. The elongated members each include a distal end and a proximal end. The proximal ends of the elongated members are coupled to the body and the distal ends of the elongated members include respective couplers. The electronic device holder further includes a second securing member coupled to the body such that relative lateral and/or longitudinal movement between the second securing member and the body is permitted. The proximal end of the second securing member is coupled to the body during use and the distal end of the second securing member includes a coupler. The couplers of the first and second securing members are coupleable to respective exterior portions of the electronic device during use such that relative movement between the electronic device and the body is inhibited. The electronic device holder still further includes a support member coupled to the body. The support member includes an external shape grippable by a human hand such that a user can securely hold the electronic device by clutching the support member during use. During use, the support member bears at least a portion of the weight of the electronic device.

In some embodiments, an electronic device holder includes a body and one or more securing members coupled to the body. The securing members, during use, couple the body to an electronic device such that relative movement between the electronic device and the body is inhibited. The electronic device holder further includes a support member coupled to the body. The support member includes an external shape grippable by a human hand such that a user can securely hold the electronic device by clutching the support member during use. During use, the support member bears at least a portion of the weight of the electronic device. The support member includes one or more arms extending from the support member such that, during use, when the arms abut a surface of an external structure, the electronic device is balanced on the surface of the external structure.

In some embodiments, an electronic device stand includes a base plate and a neck coupled to the base plate and extending longitudinally therefrom. The electronic device stand further includes an electronic device holder coupled to the neck and including a body and a first securing member coupled to the body. The first securing member includes two or more elongated members extending outward from the body. The elongated members each include a distal end and a proximal end. The proximal ends of the elongated members are coupled to the body and the distal ends of the elongated members include respective couplers. The electronic device further includes a second securing member coupled to the body such that relative lateral and/or longitudinal movement between the second securing member and the body is permitted. The proximal end of the second securing member is coupled to the body during use and the distal end of the second securing member includes a coupler. The couplers of the first and second securing members are coupleable to respective exterior portions of the electronic device during use such that relative movement between the electronic device and the body is inhibited. The electronic device still further includes a support member coupled to the body. The support member bears at least a portion of the weight of the electronic device during use.

In some embodiments, a method of holding an electronic device includes coupling an electronic device holder to the electronic device such that relative movement between the electronic device and the electronic device holder is inhibited. Coupling the electronic device holder to the electronic device includes attaching a coupler of the electronic device holder to an exterior portion of the electronic device. The method further includes clutching a grippable support member of the electronic device holder such that the electronic device is securely held. The method still further includes adjusting the angular position of the electronic device with respect to the support member.

In further embodiments, additional features may be added to the specific embodiments described herein.

### BRIEF DESCRIPTION OF THE DRAWINGS

The present invention will be better understood and other advantages will appear on reading the detailed description of some embodiments taken as non-limiting examples and illustrated by the following drawings in which:

FIG. 1 is a front perspective view of an electronic device holder coupled to an electronic device in accordance with one or more embodiments;

FIG. 2 is a rear perspective view of the electronic device holder in accordance with one or more embodiments;

FIG. 3 is a front view of a body of the electronic device holder in accordance with one or more embodiments;

FIG. 4 is a side view of a body of the electronic device holder in accordance with one or more embodiments;

FIG. 5 is a rear view of a body of the electronic device holder in accordance with one or more embodiments;

FIG. 6 is a perspective view of a portion of a first securing member of the electronic device holder in accordance with one or more embodiments;

FIG. 7 is a perspective view of a second securing member of the electronic device holder in accordance with one or more embodiments;

FIG. 8 is a rear view of the electronic device holder depicting the second securing member in a first biased longitudinal position in accordance with one or more embodiments;

FIG. 9 is a rear view of the electronic device holder depicting the second securing member in a second biased longitudinal position in accordance with one or more embodiments;

FIG. 10 is a front view of a support member of the electronic device holder in accordance with one or more embodiments;

FIG. 11 is a side view of a support member of the electronic device holder in accordance with one or more embodiments;

FIG. 12 is a rear view of a support member of the electronic device holder in accordance with one or more embodiments;

FIGS. 13A-13C are side views illustrating relative angular movement between the support member and the body of the electronic device;

FIGS. 14A-14E are progressive side views illustrating a method of coupling the electronic device holder to the electronic device in accordance with one or more embodiments; and

FIG. 15 is a side view of an electronic device stand in accordance with one or more embodiments.

While the invention is susceptible to various modifications and alternative forms, specific embodiments thereof are shown by way of example in the drawings and will herein be described in detail. It should be understood, however, that the drawing and detailed description thereto are not intended to limit the invention to the particular form disclosed, but on the contrary, the intention is to cover all modifications, equivalents and alternatives falling within the spirit and scope of the present invention as defined by the appended claims.

### DETAILED DESCRIPTION OF ILLUSTRATIVE EMBODIMENTS

It is to be understood that the present invention is not limited to particular devices or methods, which may, of course, vary. It is also to be understood that the terminology used herein is for the purpose of describing particular embodiments only, and is not intended to be limiting. As used in this specification and the appended claims, the singular forms “a”, “an”, and “the” include singular and plural referents unless the content clearly dictates otherwise. Thus, for example, reference to “a member” may include a combination of two or more members. Furthermore, the word “may” is used throughout this application in a permissive sense (i.e., having the potential to, being able to), not in a mandatory sense (i.e., must). The term “include,” and derivations thereof, mean “including, but not limited to.” Terms relating to orientation, such as “upper”, “lower”, “top”, “bottom”, “left”, or “right”, are used for reference only; the device herein may be used in any orientation. The order of any method may be changed, and various elements may be added, reordered, combined, omitted, modified, etc.

In the context of this application, the following terms are defined as:

The term “coupled” means either a direct connection or an indirect connection (e.g., one or more intervening connections) between one or more objects or components. The phrase “directly connected” means a direct connection between objects or components such that the objects or components are connected directly to each other so that the objects or components operate in a “point of use” manner.

A “body” refers to any physical structure capable of at least partially supporting another object. A body may have various regular or irregular shapes. For example, portions of a body may be straight, curved, or a combination of both.

A “mechanical fastener” refers to a fastener that is used to couple two or more elements together by mechanical/physical force. Examples of a mechanical fastener include, but are not limited to, a bolt, a pin, a rivet, a wire, and any combination of such elements.

A “member” refers to a constituent part of a system. A “member” may include a plate, link, rod, or other structure of various sizes, shapes, and forms. A member may be a single component or a combination of components coupled to one another. A member may have various regular or irregular shapes. For example, portions of a member may be straight, curved, or a combination of both.

The term “elongated” means having more length than width.

An “opening” refers to an aperture, such as a hole, gap, slit, or slot.

An “elongated member” refers to any member of the system, device, or apparatus having more length than width.

A “bias member” refers to any member of the system, device, or apparatus which exerts a force in a particular direction(s).

A “coupler” refers to any physical structure capable of releasably or permanently connecting two objects. Examples of a coupler include, but are not limited to, a hook, an elastic harness, a clip, a noose, a clasp, and any combination of such elements.

A “locking mechanism” refers to a fastening device capable of coupling one or more objects to an external structure or one another.

The term “proximal” refers to the portion of a structure which is closest to a point of reference.

The term “distal” refers to the portion of a structure which is furthest from a point of reference.

The term “rubber” refers to any elastic polymeric materials. The term “rubber” includes synthetic and natural rubbers. Examples of synthetic rubbers include, but are not limited to: poly (bromo isobutylene isoprene); polybutadiene; poly (chloro isobutylene isoprene); polychloroprene; poly (chlorosulphonated polyethylene); poly (epichlorohydrin); poly (ethylene propylene); poly (ethylene propylene diene monomer); poly (fluoronated hydrocarbon); poly (fluoro silicone); poly (hydrogenated nitrile butadiene); polyisoprene; poly (isobutylene isoprene butyl); poly (methyl vinyl silicone); poly (acrylonitrile butadiene); polyurethane; poly (styrene butadiene); poly (styrene ethylene/butylene styrene); polysiloxane; and poly (acrylonitrile butadiene carboxy monomer).

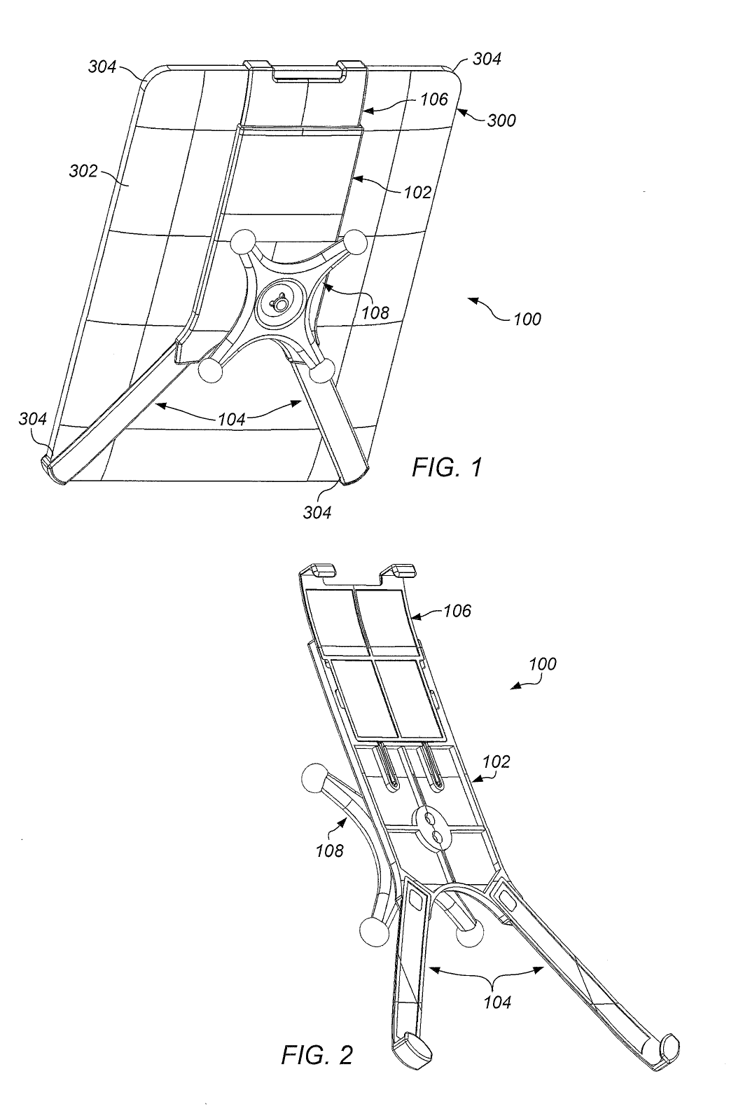

FIG. 1 is a front perspective view of an electronic device holder 100 coupled to an electronic device 300 in accordance with one or more embodiments. FIG. 2 is a rear perspective view of electronic device holder 100 in accordance with one or more embodiments. In some embodiments, electronic device holder 100 may include a body, as well as one or more securing members and a support member coupled to the body. For example, in the illustrated embodiment, electronic device holder 100 includes body 102, first securing member 104, second securing member 106, and support member 108. In some embodiments, one or more members of electronic device holder 100 (e.g., first securing member 104, second securing member 106, and/or support member 108) are formed integrally with body 102. In some embodiments, one or more members of electronic device holder 100 are formed separately from body 102 and subsequently coupled thereto. During use, one or more securing members of electronic device holder 100 may couple body 102 (releasably or permanently) to electronic device 300. For example, in the illustrated embodiment, body 102 may be coupled to electronic device 300 via first and second securing members 104 and 106 such that relative movement between electronic device 300 and body 102 is inhibited. It will be appreciated, however, that electronic device holder 100 may include any number of securing members for coupling body 102 to electronic device 300.

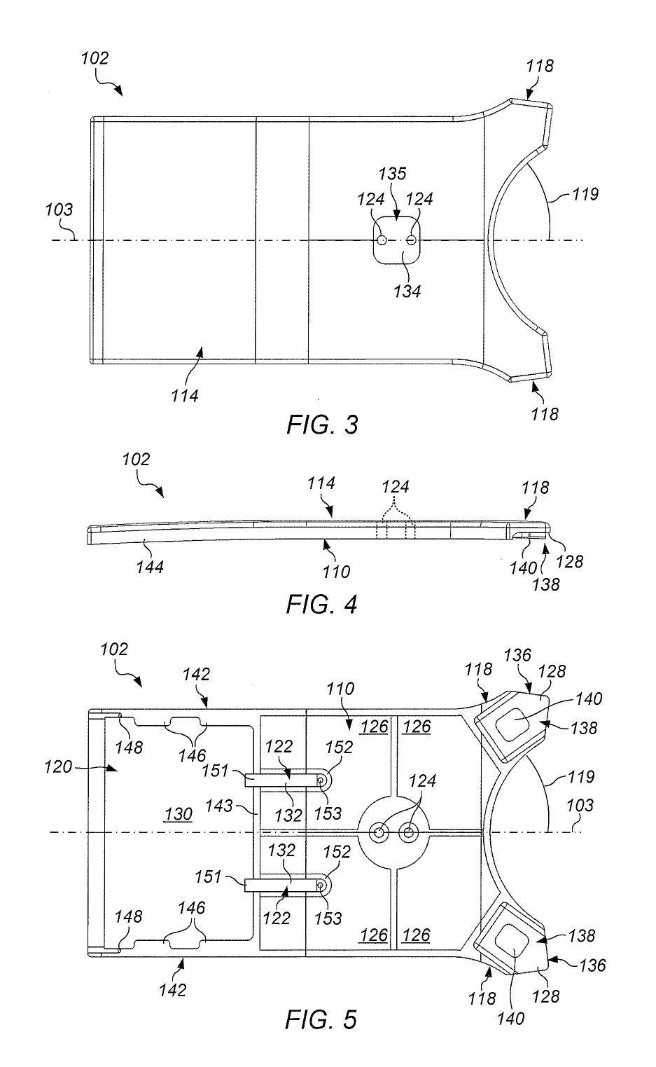

FIGS. 3-5 are front, side, and rear views of body 102 in accordance with one or more embodiments. Body 102 may be composed of any suitable material. For example, body 102 may be composed of a metal, polymeric material, or mixtures and combinations thereof. In some embodiments, body 102 includes one or more inner surfaces and/or outer surfaces composed of a material including a slip resistant material (in some embodiments, a slip resistant surface may be formed by texturing or surface treatment). For example, the inner surfaces and/or outer surfaces of body 102 may include one or more surfaces having a coefficient of friction sufficient to inhibit sliding between body 102 and an external surface (e.g., outer surface 302 of electronic device 300 and/or a user's hand). Body 102 may have any suitable shape. For example, in the illustrated embodiment, the majority of body 102 is substantially rectangular. In some embodiments, body 102 is substantially symmetrical. For example, in the illustrated embodiment, body 102 is substantially symmetrical about centerline 103. In some embodiments, body 102 includes inner face 110, outer face 114, shoulders 118, slot 120, channel openings 122, and apertures 124. Inner face 110 and/or outer face 114 of body 102 may include a combination of straight and curved surfaces. In some embodiments, one or more surfaces of body 102 are complementary to one or more outer surfaces of electronic device 300. For example, in the illustrated embodiment, inner face 110 of body 102 includes one or more concave surfaces corresponding to the convex shape of outer surface 302 of electronic device 300. The concave surfaces of body 102 may be in direct contact with at least a portion of outer surface 302 of electronic device 300 (see FIG. 1) during use. In certain embodiments, the concave surfaces of body 102 may be in direct contact with at least a majority of outer surface 302 of electronic device 300 during use. Inner face 110 and/or outer face 114 may include one or more raised or recessed surfaces. For example, in the illustrated embodiment, inner face 110 includes recessed surfaces 126, 128, 130, and 132; and outer face 114 includes recessed surface 134. Forming body 102 with one or more recessed surfaces may advantageously reduce the material usage (and thus the costs) associated with manufacturing electronic device holder 100 without significantly affecting the structural integrity of body 102. For example, in the illustrated embodiment, recessed surfaces 126 may be provided in areas of body 102 that bear relatively little or no load during use. In some embodiments, one or more recessed surfaces may define an opening for receiving a constituent member of electronic device holder 100. For example, in the illustrated embodiment, recessed surface 134 of outer face 114 defines opening 135 for receiving a portion of support member 108 during use (see FIG. 3). One or more apertures may be located proximate recessed surface 134 for coupling support member 108 to body 102. For example, in the illustrated embodiment, body 102 includes two apertures 124 located on recessed surface 134. Apertures 124 may be through-holes. For example, in the illustrated embodiment, apertures 124 pass through recessed surface 134. In some embodiments, apertures 124 may include a selected interior thread pattern. During use, apertures 124 may receive one or more mechanical fasteners for coupling support member 108 to body 102.

In some embodiments, body 102 includes shoulders 118. Shoulders 118 may extend outward from body 102. For example, in the illustrated embodiment, shoulders 118 extend outward obliquely from body 102 at a selected angle 119 with respect to a centerline 103 of body 102. In some embodiments, selected angle 119 is less than about 45°. During use, shoulders 118 may be coupled to, and at least partially support, one or more portions of first securing member 104. In some embodiments, shoulders 118 include quick coupling joints 136. Quick coupling joints 136 may include recessed surfaces 128 defining openings 138 and tabs 140 for friction mating with portions of first securing member 104. In some embodiments, the friction interfaces between the mating portions of securing member 104 and quick coupling joints 136 may be sufficient to inhibit unintentional separation of first securing member 104 from body 102.

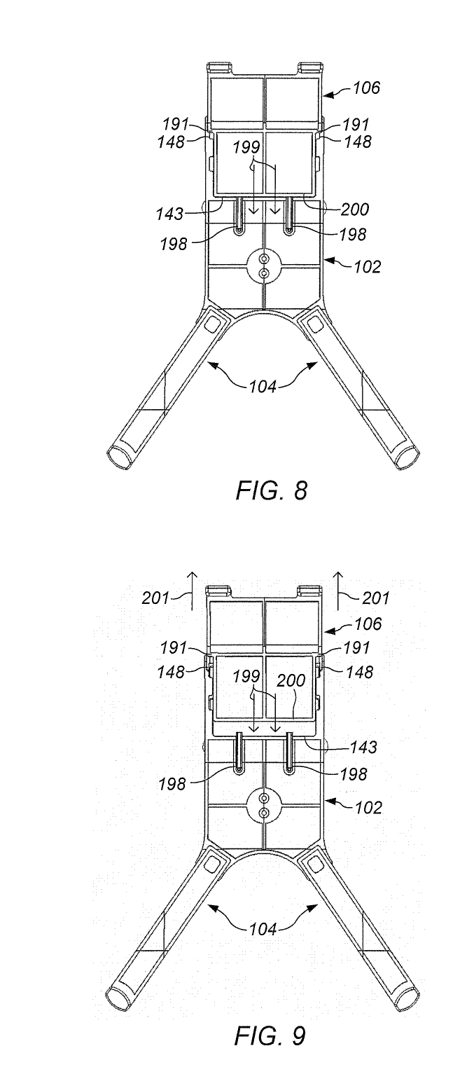

In some embodiments, body 102 includes slot 120 (see FIG. 5). In some embodiments, slot 120 receives at least a portion of second securing member 106 during use. Slot 120 may be any suitable size or shape for receiving at least a portion of second securing member 106. For example, in the illustrated embodiment, slot 120 is substantially rectangular. Slot 120 may be at least partially delimited by recessed surface 130, tracks 142, and lower lateral edge 143. Tracks 142 may include side walls 144, protrusions 146, and ridges 148. In some embodiments, tracks 140 guide relative lateral and/or longitudinal movement between second securing member 106 and body 102. For example, in the illustrated embodiment, tracks 140 may guide relative longitudinal movement between second securing member 106 and body 102 (see FIGS. 8-9).

In some embodiments, body 102 includes channel openings 122. Channel openings 122 may be defined by recessed surfaces 132 and 126. Channel openings 122 may include open end 151 and closed end 152. During use, channel openings 122 may house one or more biasing members (e.g., a spring or an elastic band; see FIGS. 8-9). In some embodiments, channel openings 122 include pins 153 disposed proximate closed end 152. Pins 153 may couple the biasing members to body 102 during use.

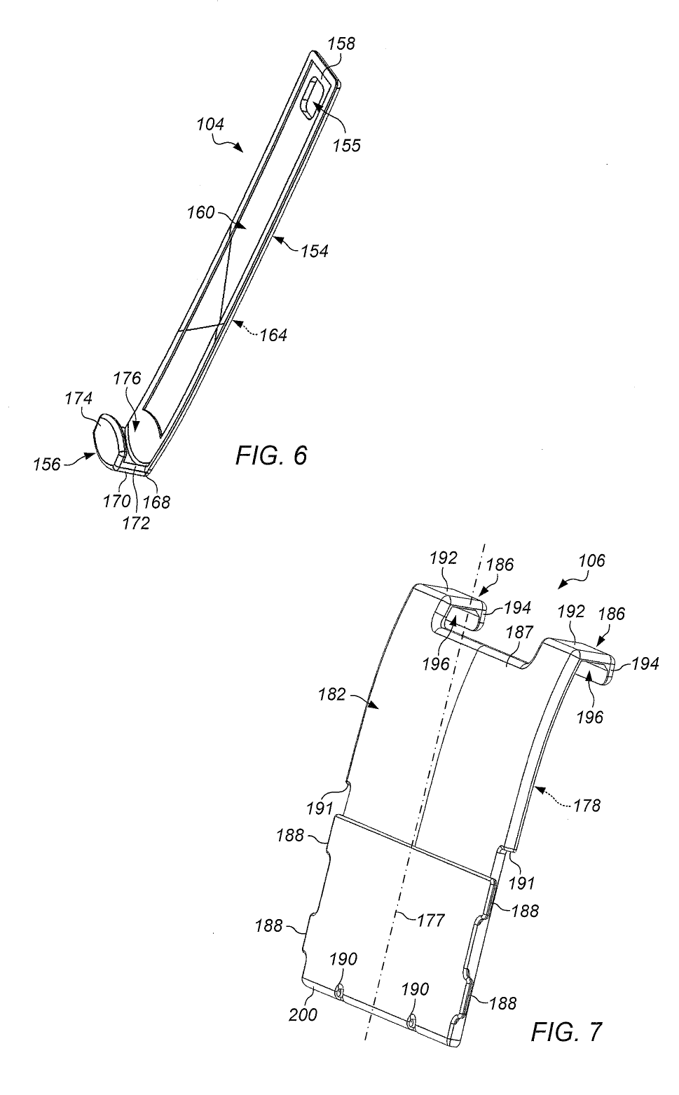

FIG. 6 is a perspective view of a portion of first securing member 104 in accordance with one or more embodiments. First securing member 104 may be coupled to body 102 (see FIGS. 1-2). For example, first securing member 104 may be formed integrally with body 102, attached to body 102 via mating portions of quick coupling and release joints or otherwise secured to body 102 (e.g., via adhesive, etc.). First securing member 104 may include any number of elongated members and couplers, the couplers being attachable to an exterior portion of electronic device 300 during use. For example, in the illustrated embodiment, first securing member 104 includes two elongated members 154 and two couplers 156. In some embodiments, shoulders 118 at least partially support elongated members 154. Elongated members 154 may be composed of any suitable material. For example, elongated members 154 may be composed of a metal, polymeric material, or mixtures and combinations thereof. Elongated members may have any suitable shape. Elongated members 154 may be any suitable shape and/or size. For example, in the illustrated embodiment, elongated members have an elongated polygonal shape. Elongated members 154 may include inner faces 160, outer faces 164, and openings 155. In some embodiments, one or more surfaces of elongated members 154 are complementary to outer surface 302 of electronic device 300. For example, in the illustrated embodiment, inner faces 160 of elongated members 154 include one or more concave surfaces corresponding to the convex shape of outer surface 302 of electronic device 300. The concave surfaces of elongated members 154 may be in direct contact with at least a portion of outer surface 302 of electronic device 300 during use. In some embodiments, first securing member 104 includes one or more inner surfaces and/or outer surfaces composed of a material including one or more slip resistant materials. Elongated members 154 may extend outward from body 102. For example, in the illustrated embodiment, elongated members 154 extend outward obliquely from body 102 toward corners 304 of electronic device 300 (see FIG. 1) during use. In some embodiments, elongated members 154 extend obliquely from body 102 at selected angle 119 with respect to centerline 103 of body 102. In certain embodiments, the selected angle at which elongated members 154 extend from body 102 is adjustable. In such embodiments, electronic device holder 100 may be coupled to several different electronic devices having different sizes and/or shapes. In some embodiments, proximal ends 158 of elongated members 154 (with respect to body 102) are coupled to body 102 via quick coupling joints 136 of shoulders 118. For example, in the illustrated embodiment, proximal ends 158 of elongated members 154 are received by openings 138 of quick coupling joints 136; and tabs 140 of quick coupling joints 136 are received by openings 155 of elongated members 154 (see FIG. 2).

One or more couplers 156 of first securing member 104 may be formed on or near an end of elongated members 114. For example, in the illustrated embodiment, couplers 156 are formed proximate distal ends 168 (with respect to body 102) of elongated members 154. Couplers 156 may be composed of any suitable material. For example, couplers 156 may be composed of a rubber (i.e., an elastic polymer). In some embodiments, couplers 156 include one or more inner surfaces and/or outer surfaces composed of a material including one or more slip resistant materials. Couplers 156 may include base portions 170, side walls 172, and inner walls 174. Base portions 170, side walls 172, and inner walls 174 may define openings 176 for receiving respective exterior portions of electronic device 300 during use. For example, in the depicted embodiment, openings 176 of couplers 156 receive adjacent corners 304 of electronic device 300 (see FIG. 1). In some embodiments, base portions 170, side walls 172, and inner walls 174 of couplers 156 may physically protect at least a portion of electronic device 300 from an impact, such as if electronic device 300 were dropped.

FIG. 7 is a perspective view of second securing member 106 in accordance with one or more embodiments. Second securing member 106 may be composed of any suitable material. For example, second securing member 106 may be composed of a metal, polymeric material, or mixtures and combinations thereof. Second securing member 106 may be any suitable shape and/or size. For example, in the illustrated embodiment, at least a portion of second securing member 106 is substantially rectangular. In some embodiments, second securing member 106 is substantially symmetrical. For example, in the illustrated embodiment, second securing member 106 is substantially symmetrical about centerline 177. Second securing member 106 may be coupled to body 102 (see FIGS. 1-2). For example, in the illustrated embodiment, during use, at least a portion of second securing member 106 is disposed in slot 120. Second securing member 106 may include inner face 178 and outer face 182. In some embodiments, one or more surfaces of second securing member 106 are complementary to one or more outer surfaces of electronic device 300. For example, in the illustrated embodiment, inner face 178 of second securing member 106 includes one or more concave surfaces corresponding to the convex shape of outer surface 302 of electronic device 300. The concave surfaces of second securing member 106 may be in direct contact with at least a portion of outer surface 302 of electronic device 300 during use (see FIG. 1). In some embodiments, second securing member 106 includes one or more inner surfaces and/or outer surfaces composed of a material including a slip resistant material. Inner face 178 and/or outer face 182 may include one or more raised or recessed surfaces (not shown). Forming second securing member 106 with one or more recessed surfaces may advantageously reduce the material usage (and thus the costs) associated with manufacturing electronic device holder 100 without significantly affecting the structural integrity of second securing member 106. For example, the recessed surfaces may be provided in areas of second securing member 106 that bear relatively little or no load during use. In some embodiments, second securing member 106 further includes couplers 186, tabs 188, pins 190, and lateral shelves 191. One or more couplers 186 may be formed on or near an end of second securing member 106. For example, in the illustrated embodiment, second securing member 106 includes two couplers 186 formed near distal end 187 (with respect to body 102) of the second securing member. Couplers 186 may be composed of any suitable material. For example, couplers 186 may be composed of a rubber (i.e., an elastic polymer). Couplers 186 may include base portions 192 and inner walls 194. Base portions 192 and inner walls 194 may define openings 196 for receiving respective portions of electronic device 300 (see FIG. 1). In some embodiments, base portions 192 and inner walls 194 of couplers 186 may physically protect at least a portion of electronic device 300 from an impact, such as if electronic device 300 were dropped.

In some embodiments, second securing member 106 is movably coupled to body 102 such that relative lateral and/or longitudinal movement between securing member 106 and body 102 is permitted. For example, in the illustrated embodiment, during use, tabs 188 may contact side walls 144 of tracks 142 (of body 102) such that relative lateral movement between securing member 106 and body 102 is inhibited while relative longitudinal movement between securing member 106 and body 102 is permitted. In some embodiments, sliding is permitted between tabs 188 and side walls 144. In certain embodiments, sliding between tabs 188 and side walls 144 is enhanced by application of a lubricant. Protrusions 146 of tracks 142 of body 102 may at least partially inhibit relative lateral movement between securing member 106 and body 102. For example, in the illustrated embodiment, protrusions 146 at least partially enclose the inner lateral side of slot 120. In certain other embodiments, protrusions 146 completely enclose the inner lateral side of slot 120.

FIG. 8 is a rear view of electronic device holder 100 depicting second securing member 106 in a first biased longitudinal position. FIG. 9 is a rear view of electronic device holder 100 depicting second securing member 106 in a second biased longitudinal position. In some embodiments, second securing member 106 is coupled to body 102 such that biased, lateral and/or longitudinal movement between second securing member 106 and body 102 is permitted. For example, in the illustrated embodiment, bias members 198 are coupled to pins 153 of body 102 and pins 190 of second securing member 106 such that second securing member 106 is urged longitudinally towards body 102 and vice versa. For example, in the illustrated embodiment, bias members 198 may impart a biasing force 199 on second securing member 106 during use. In some embodiments, a first biased longitudinal position is a lowered position. As depicted in FIG. 8, when second securing member 106 is in the first biased longitudinal position, proximal end 200 of second securing member 106 may abut lower lateral edge 143 of body 102; lateral shelves 191 of second securing member 106 may abut ridges 148 of body 102; and bias members 198 may experience little or no elastic or plastic deformation (e.g., stretching). Lower lateral edge 143 and ridges 148 may inhibit further lowering of the second securing member during use. In some embodiments, a second biased longitudinal position is a raised position. In some embodiments, an external force 201 opposing biasing force 199 may be applied to securing member 106 such that the securing member is raised relative to body 102. As depicted in FIG. 9, when second securing member 106 is in a second biased longitudinal position, bias members 198 may endure significant elastic deformation (e.g., stretching) and the second securing member may be suspended in a raised position.

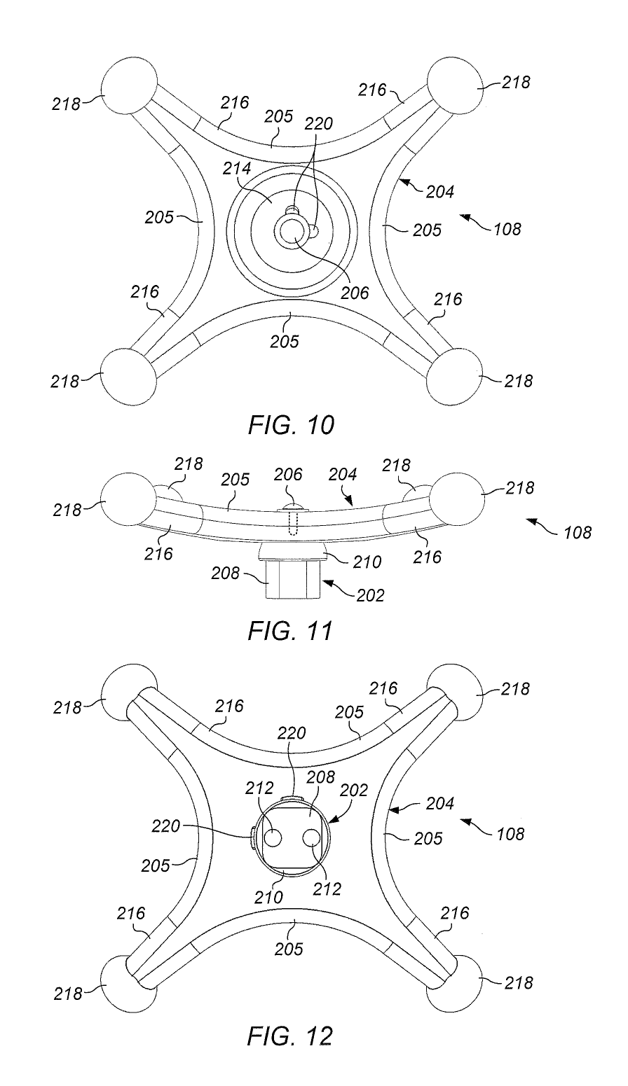

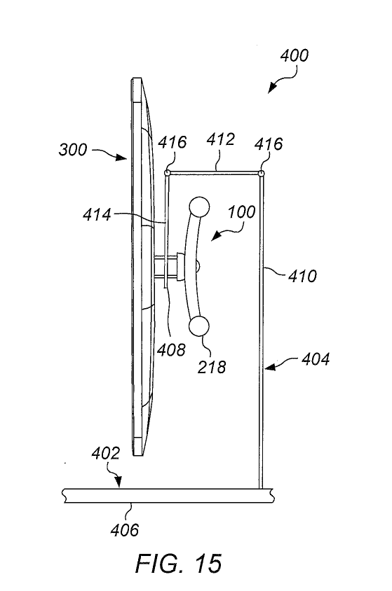

FIGS. 10-12 are front, side, and rear views of support member 108 in accordance with one or more embodiments. Support member 108 may be coupled to body 102 (see FIG. 1). For example, support member 108 may be formed integrally with body 102 or attached to body 102 via quick coupling, one or more mechanically fasteners, and/or an adhesive, etc. In certain embodiments, support member 108 may be coupled to body 102 at or near the geometric center of the body. Support member 108 may be any suitable shape (e.g., a knob or a handle) and/or size. For example, a suitable external shape and/or size of support member 108 may be grippable by a human hand such that a user can securely hold electronic device 200 by clutching support member 108 during use. In some embodiments, support member 108 is at least substantially symmetric about an axis passing though the geometric center of the support member. For example, in certain embodiments, support member 108 is at least substantially symmetric about a majority of axes passing through the geometric center of the support member. Support member 108 may be composed of any suitable material. For example, support member 108 may be composed of a metal, polymeric material, or mixtures and combinations thereof. In some embodiments, support member 108 includes one or more inner surfaces and/or outer surfaces composed of a material including a slip resistant material. In some embodiments, support member 108 includes neck 202, head 204, and end cap 206. In some embodiments, support member 108 may bear at least a portion of the weight of electronic device 300 during use. In certain embodiments, support member 108 bears at least a majority of the weight of electronic device 300 during use. For example, in the illustrated embodiment, neck 202 may bear at least a portion of the weight of electronic device 300 during use. Neck 202 may include base portion 208 and convex portion 210. In some embodiments, neck 202 may be attached to body 102. For example, in the illustrated embodiment, base portion 208 may be at least partially disposed within opening 128 defined by recessed surface 134 of body 102 (see FIG. 1). Base portion 208 may include apertures 212 for receiving one or more mechanical fasteners (not shown). In some embodiments, apertures 212 may include a selected internal thread pattern. In some embodiments, apertures 212 of neck 202 are aligned with apertures 124 of body 102 such that a single mechanical fastener may traverse at least a portion of both body 102 and neck 202. For example, a mechanical fastener may be inserted through apertures 212 and 124 from inner face 110 of body 102. Base portion 208 may be any suitable shape and/or size. For example, in the illustrated embodiment, base portion 208 is formed with a substantially rectangular cross-section. In some embodiments, base portion 208 includes a plurality of substantially flat surfaces. The substantially flat surfaces of base portion 208 may be received by an opening of an electronic device stand (see FIG. 15).

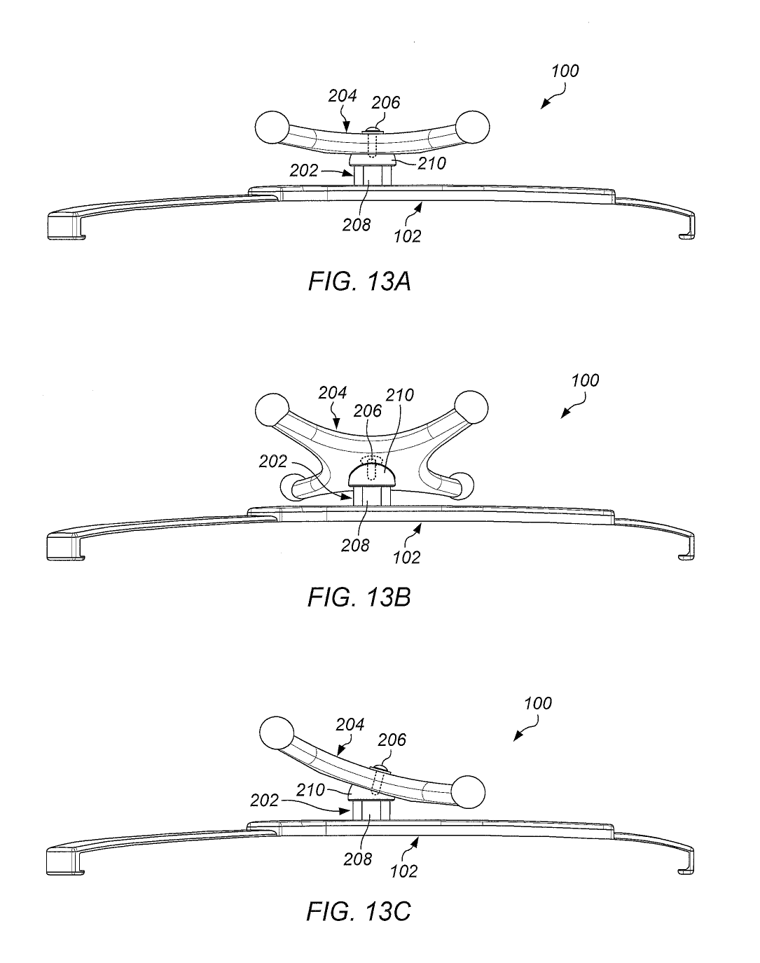

Head 204 may include an ergonomic external shape such that it may be relatively easily and comfortably gripped/clutched by a user. For example, in the illustrated embodiment, head 204 includes a plurality of concave surfaces 205. During use, a user's fingers and thumb may be curled around concave surfaces 205 to clutch support member 108. Head 204 may include socket 214, arms 216, and bulbous members 218. Socket 214 may have a shape complementary to convex portion 210 of neck 202. For example, in the illustrated embodiment, the inner face (not shown) of socket 214 may include one or more concave surfaces corresponding to the shape of convex portion 210. In certain embodiments, the concave surfaces of socket 214 may be in direct contact with the exterior surface of convex portion 210. In some embodiments, socket 214 further includes one or more slots 220. In certain embodiments, slots 220 extend from a location at or near the geometric center of socket 214. During use, slots 220 may guide relative angular movement between support member 108 and body 102. Socket 214 may include any number of slots 220. In some embodiments, support member 108 is coupled to body 102 such that support member 108 is angularly movable in three planes (including various combinations of movement in such planes) relative to body 102 (and thus electronic device 300), during use. FIGS. 13A-13C are side views illustrating relative angular movement between support member 108 and body 102. In certain embodiments, convex portion 210 of neck 202, socket 214 and end cap 206 may collectively form a ball-and-socket coupling. For example, in the illustrated embodiment, a cylindrical portion of end cap 206 extends at least partially through slots 220 and an opening (not shown) located proximate the geometric center of convex portion 210, thereby coupling socket 214 and neck 202 to one another and pressing the inner concave surfaces of socket 214 against the outer surface of convex portion 210. In some embodiments, the cylindrical portion of end cap 206 includes an external thread pattern; the opening located on the external surface of convex portion 210 may include a complementary internal thread pattern such that socket 214 and convex portion 210 are held together via frictional interfaces between adjacent/abutting threads. In some embodiments, the resistive forces (e.g., frictional forces) of the ball-and-socket coupling are sufficient to inhibit unintentional movement of support member 108 relative to body 102. For example, the frictional interface between the inner concave surfaces of socket 214 and the outer surface of convex portion 210 may be sufficient to inhibit unintentional movement of support member 108 relative to body 102. In some embodiments, support member 108 includes a locking mechanism to hold support member 108 at a selected angle relative to body 102 during use. For example, the ball-and-socket coupling may include such a locking mechanism.

Head 204 may include one or more arms 216. For example, in the illustrated embodiment, head 204 includes four arms 216 extending outward from the geometric center of head 204. Bulbous members 218 may be coupled to arms 216. For example, in the illustrated embodiment, bulbous members 218 are coupled to the distal ends (with respect to body 102) of arms 216. In some embodiments, the respective distal ends of arms 216 are equidistant from the geometric center of head 204. In certain embodiments, when a portion of one or more of arms 216 abuts a surface of an external structure, the electronic device is balanced on the surface of the external structure. For example, in the illustrated embodiment, electronic device 300 may be balanced on the surface of an external surface when two or more bulbous members 218 abut the external surface.

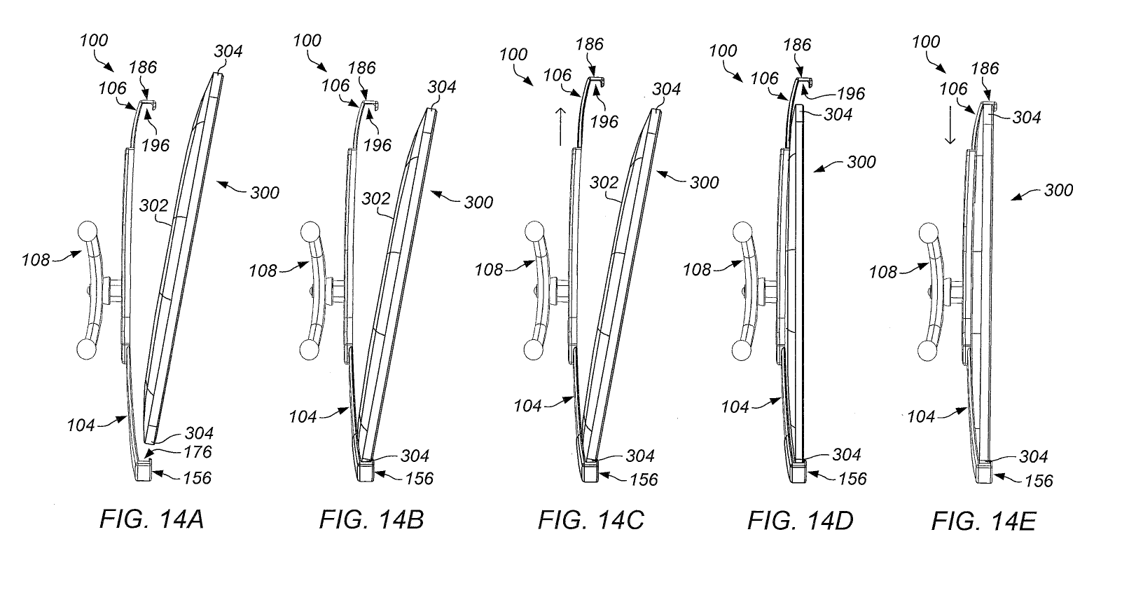

FIGS. 14A-14E are progressive side views illustrating a method of coupling electronic device holder 100 to electronic device 300 in accordance with one or more embodiments. In some embodiments, electronic device holder 100 may be coupled to the electronic device 300 such that relative movement between electronic device 300 and electronic device holder 100 is inhibited. Coupling electronic device holder 100 to electronic device 300 may include attaching couplers 156 of first securing member 104 to a first exterior portion(s) of the electronic device. For example, in the illustrated embodiment, adjacent corners 304 of electronic device 300 are inserted at least partially into openings 176 of couplers 156, as depicted in FIGS. 14A-14B. Coupling electronic device holder 100 to electronic device 300 may further include attaching couplers 186 of second securing member 106 to a second exterior portion(s) of electronic device 300. For example, in the illustrated embodiment, second securing member 106 is adjusted from a first position (i.e., a lowered position) to a second position (i.e., a raised position), as depicted in FIG. 14C; electronic device 300 may then be pressed against the inner side of electronic device holder 100, as depicted in FIG. 14D; second securing member 106 may then be released permitting the second exterior portion(s) of electronic device 300 to be at least partially inserted into openings 196 of couplers 186, as depicted in FIG. 14E.

In some embodiments, a method of holding an electronic device includes coupling electronic device holder 100 to electronic device 300; clutching support member 108 of electronic device holder 100 such that the device is securely held; and adjusting the angular position of electronic device 300 with respect to support member 108 (or vice versa).

FIG. 15 is a side view of an electronic device stand 400 in accordance with one or more embodiments. In some embodiments, electronic device stand 400 includes base plate 402, post 404, and electronic device holder 100. Electronic device holder 100 may be coupled to electronic device 300. In some embodiments, base plate 402 includes one or more surfaces 406 abutting the surface of an external structure during use such that electronic device 300 is balanced on the surface of the external structure. For example in the illustrated embodiment, surface 406 is substantially flat. Base plate 402 may be any suitable shape and/or size for balancing electronic device 300 on the surface of an external structure. In some embodiments, post 404 includes coupler 408 as well as elongated members 410, 412, and 414. Post 404 may be coupled to base plate 402. For example, in the illustrated embodiment, elongated member 410 may be coupled to base plate 402 and extending longitudinally therefrom. In some embodiments, elongated members 410, 412, and 414 may be coupled to one another via one or more adjustable hinges 416. Coupler 408 may be attached to electronic device holder 100. For example, in the illustrated embodiment, the neck of electronic device holder 100 may be received in an opening of coupler 408.

Further modifications and alternative embodiments of various aspects of the invention may be apparent to those skilled in the art in view of this description. Accordingly, this description is to be construed as illustrative only and is for the purpose of teaching those skilled in the art the general manner of carrying out the invention. It is to be understood that the forms of the invention shown and described herein are to be taken as embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

1. An electronic device holder comprising:
a body;
one or more securing members coupled to the body, wherein the securing members, during use, couple the body to an electronic device such that relative movement between the electronic device and the body is inhibited;
a support member coupled to the body, the support member comprising an external shape grippable by a human hand such that a user can securely hold the electronic device by clutching the support member during use,
wherein, during use, the support member bears at least a portion of the weight of the electronic device, and
wherein the support member is coupled to the body such that the support member is angularly movable in three planes relative to the body during use.

2. (canceled)

3. The electronic device holder of claim 1, wherein an inner surface of the body is complementary to an outer surface of the electronic device such that, during use, the inner surface of the body is in direct contact with at least a majority of the outer surface of the electronic device.

4. The electronic device holder of claim 1, wherein an inner surface and/or an outer surface of the body is composed of a material comprising a slip resistant material.

5. The electronic device holder of claim 1, wherein at least one securing member comprises a coupler, the coupler being attachable to an exterior portion of the electronic device during use, and wherein the coupler comprises an opening for receiving the exterior portion of the electronic device during use.

6. (canceled)

7. (canceled)

8. The electronic device holder of claim 5, wherein the coupler is composed of a material comprising an elastic polymer.

9. The electronic device holder of claim 5, wherein the coupler comprises an elastic harness.

10. The electronic device holder of claim 1, wherein at least one securing member is coupled to the body such that, during use, relative lateral and/or longitudinal movement between the securing member and the body is permitted.

11. The electronic device holder of claim 10, further comprising a bias member coupled to the body and the securing member such that, during use, the bias member urges the securing member towards the body.

12. The electronic device holder of claim 10, wherein the body comprises one or more tracks for guiding relative lateral and/or longitudinal movement between the securing member and the body during use.

13. The electronic device holder of claim 10, wherein the body comprises a slot in which at least a portion of the securing member is disposed.

14. The electronic device holder of claim 1, wherein at least one securing member comprises two or more elongated members extending outward from the body, the elongated members comprising a distal end and a proximal end, and wherein the distal end comprises a coupler.

15. (canceled)

16. The electronic device holder of claim 1, wherein the external shape of at least a portion of the support member comprises an ergonomic shape comprising one or more concave surfaces.

17. The electronic device holder of claim 1, wherein the support member is coupled to the body via a ball-and-socket coupling, wherein the resistive forces of the ball-and-socket coupling are sufficient to inhibit unintentional movement of the support member relative to the body.

18. (canceled)

19. The electronic device holder of claim 1, wherein the support member comprises a locking mechanism to hold the support member at a selected angle relative to the body during use.

20. The electronic device holder of claim 1, wherein the support member is pivotally coupled to a portion of the body proximate the geometric center of the body.

21. The electronic device holder of claim 1, wherein the support member is at least substantially symmetrical about one or more axes passing through the geometric center of the support member.

22. The electronic device holder of claim 1, wherein the support member comprises one or more arms extending from the geometric center of the support member such that, during use, when the arms abut a surface of an external structure, the electronic device is balanced on the surface of the external structure.

23. (canceled)

24. The electronic device holder of claim 22, wherein a distal end of each arm is equidistant from the geometric center of the support member.

25. (canceled)

26. An electronic device holder comprising:
a body;
one or more securing members coupled to the body, wherein the securing members, during use, couple the body to an electronic device such that relative movement between the electronic device and the body is inhibited;
a support member coupled to the body, the support member comprising an external shape grippable by a human hand such that a user can securely hold the electronic device by clutching the support member during use,
wherein, during use, the support member bears at least a portion of the weight of the electronic device; and
wherein the support member comprises one or more arms extending from the support member such that, during use, when the arms abut a surface of an external structure, the electronic device is balanced on the surface of the external structure.

27. (canceled)

28. (canceled)

29. A method of holding an electronic device comprising:
coupling an electronic device holder to the electronic device such that relative movement between the electronic device and the electronic device holder is inhibited,
wherein coupling the electronic device holder to the electronic device comprises attaching a coupler of the electronic device holder to an exterior portion of the electronic device;
clutching a grippable support member of the electronic device holder such that the electronic device is securely held; and
adjusting the angular position of the electronic device with respect to the support member.

30. (canceled)

31. (canceled)

32. (canceled)
